(19) United States
(12) Patent Application Publication
(10) Pub. No.: US 2026/0060027 A1
(43) Pub. Date: Feb. 26, 2026

(54) SUBSTRATE PROCESSING APPARATUS AND METHOD OF SUBSTRATE PROCESSING

(71) Applicant: Kioxia Corporation, Tokyo (JP)

(72) Inventors: Kenji MASUI, Kawasaki Kanagawa (JP); Masatoshi TERAYAMA, Kawasaki Kanagawa (JP)

(73) Assignee: Kioxia Corporation, Tokyo (JP)

(21) Appl. No.: 19/375,717

(22) Filed: Oct. 31, 2025

Related U.S. Application Data
(63) Continuation of application No. 17/930,856, filed on Sep. 9, 2022.

(30) Foreign Application Priority Data
Mar. 22, 2022 (JP) 2022-046097

(51) Int. Cl. H01L 21/67; H01L 21/687

(52) U.S. Cl. CPC H01L 21/67051; H01L 21/67109; H01L 21/68764

(57) ABSTRACT

A substrate processing apparatus according to one embodiment includes a substrate holding part having a stage holding the substrate, a freezing solution supply part supplying the freezing solution to the substrate, a cooling part cooling the freezing solution to form a freezing film, and a thawing solution supply part having a nozzle extending in a first direction including a central part of the stage in a plan view, wherein an end and an other end opposite to the end of the nozzle in the first direction are located on an outer periphery outside of the central part, and the thawing solution supply part supplies a thawing solution having at least one of a different supply volume, temperature, or supply timing between the central part and the outer periphery to the substrate to thaw the freezing film.

### CROSS REFERENCE TO RELATED APPLICATION(S)

This application is based upon and claims the benefit of priority from the prior Japanese Patent Application JP2022-046097, filed on Mar. 22, 2022, the entire contents of which are incorporated herein by reference.

### FIELD

Embodiments described herein relate generally to a substrate processing apparatus and a method of substrate processing.

### BACKGROUND

A freezing cleaning technique is known as one of the cleaning techniques for removing incrustation such as particles adhering on a substrate surface. In this technique, particles and the like are removed from the surface of the substrate by freezing a freezing solution supplied on the surface of the substrate and then thawing the freezing film by supplying the thawing solution.

### BRIEF DESCRIPTION OF THE DRAWINGS

FIG. 1 is a diagram schematically showing an overall configuration of a substrate processing apparatus according to an embodiment.

FIG. 2 is a bottom view schematically showing a structure of a nozzle according to an embodiment.

FIG. 3 is a YZ sectional view of an end of long side (a position A in FIG. 2) of a nozzle according to an embodiment.

FIG. 4 is a YZ sectional view of a center of long side (a position A′ in FIG. 2) of a nozzle according to an embodiment.

FIG. 5 is an XZ sectional view of a center of short side (a position B in FIG. 2) of a nozzle according to an embodiment.

FIG. 6A is a diagram schematically showing a method of substrate processing according to an embodiment.

FIG. 6B is a diagram schematically showing a method of substrate processing according to an embodiment.

FIG. 6C is a diagram schematically showing a method of substrate processing according to an embodiment.

FIG. 6D is a diagram schematically showing a method of substrate processing according to an embodiment.

FIG. 7 is a bottom view schematically showing a structure of a nozzle according to a modified example.

FIG. 8 is a bottom view schematically showing a structure of a nozzle according to an embodiment.

FIG. 9 is a YZ sectional view of an end of long side (a position A in FIG. 8) of a nozzle according to an embodiment.

FIG. 10 is a YZ sectional view of a center of long side (a position A′ in FIG. 8) of a nozzle according to an embodiment.

FIG. 11 is an XZ sectional view of a center of short side (a position B in FIG. 8) of the nozzle according to an embodiment.

FIG. 12 is a diagram schematically showing the overall configuration of a solution supply part according to an embodiment.

FIG. 13 is a bottom view schematically showing a structure of a nozzle according to an embodiment.

FIG. 14 is a diagram showing the conditions of a substrate processing method according to an embodiment.

FIG. 15 is a diagram showing a method of substrate processing according to an embodiment.

### DETAILED DESCRIPTION

Hereinafter, a substrate processing apparatus and a method of substrate processing according to the present embodiment will be described in detail with reference to the drawings. In the following description, elements having substantially the same functions and configurations are denoted by the same reference numerals or with the same reference numerals followed by the addition of an alphabet, and will be described in duplicate only when necessary. Each of the embodiments described below exemplifies a device and a method for embodying the technical idea of this embodiment. Various changes may be made in the embodiment without departing from the spirit of the invention. These embodiments and modified examples thereof are included in the invention described in the claims and the scope of the equivalents thereof.

For the sake of clarity of description, the widths, thicknesses, shapes, and the like of the respective parts may be schematically represented compared with the actual embodiments, but are merely an example and do not limit the interpretation of the present invention. In this specification and each drawing, elements having the same functions as those described with reference to the preceding drawings are denoted by the same reference numerals, and the repetitive descriptions thereof may be omitted.

The expression “a includes A, B or C” herein does not exclude the case where a includes multiple combinations of A to C unless otherwise specified. Furthermore, these expressions do not exclude the case where a includes other elements.

In this specification, the horizontal refers to the horizontal direction (XY direction) with respect to the stage of the substrate processing apparatus, the vertical may refer to a direction (Z direction) substantially perpendicular to the horizontal direction.

The following embodiments may be combined with each other as long as there is no technical contradiction.

In each of the following embodiments will be described exemplifying a semiconductor substrate such as a silicon wafer as a substrate, the technique of the present disclosure can be applied to a substrate other than a semiconductor substrate (for example, a glass substrate, a quartz substrate, etc.) being necessary to remove incrustation on the substrate surface such as particles.

The substrate processing apparatus includes a substrate holding part having a stage holding the substrate, a freezing solution supply part supplying the freezing solution to the substrate, a cooling part cooling the freezing solution to form a freezing film, and a thawing solution supply part having a nozzle extending in a first direction including a central part of the stage in a plan view, wherein an end and an other end opposite to the end of the nozzle in the first direction are located on an outer periphery outside of the central part, and the thawing solution supply part supplies a thawing solution having at least one of a different supply volume, temperature, or supply timing between the central part and the outer periphery to the substrate to thaw the freezing film.

### First Embodiment

### [Substrate Processing Apparatus]

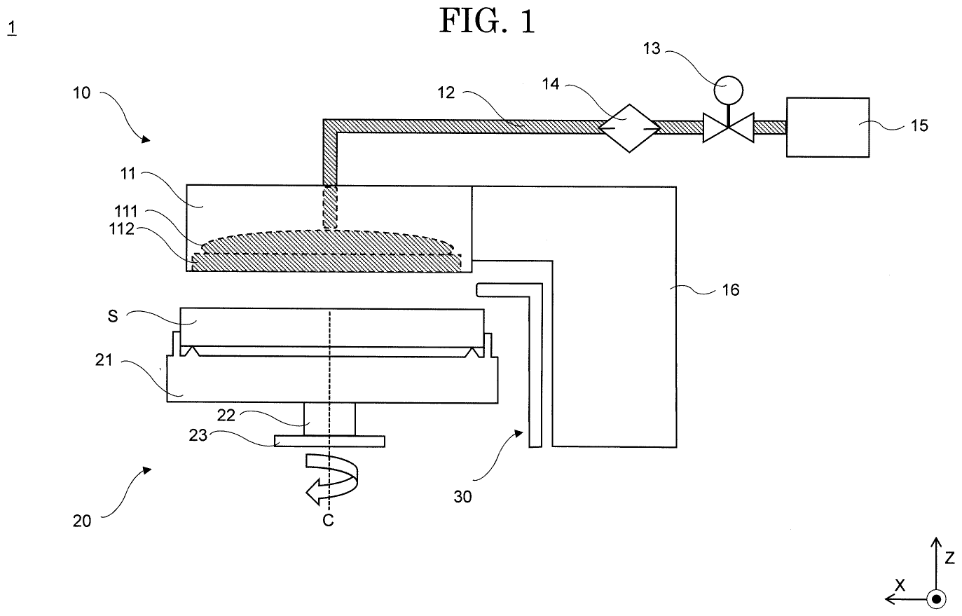

FIG. 1 is a diagram schematically showing an overall configuration of a substrate processing apparatus according to an embodiment. The substrate processing apparatus 1 according to the present embodiment is, for example, an apparatus for performing the freezing cleaning process for removing particles and the like from the substrate surface by supplying the freezing solution to the surface of the semiconductor substrate, cooling the freezing solution to form the freezing film, and thawing the freezing film by supplying the thawing solution. The surface of the semiconductor substrate is, for example, a surface on which a semiconductor device such as the three-dimensional NAND is formed. On the surface of the semiconductor substrate, for example, a circuit pattern (not shown) is formed. As shown in FIG. 1, the substrate processing apparatus 1 includes a solution supply part 10, a substrate holding part 20, and a cooling part 30.

The substrate holding part 20 includes a stage 21, a rotation mechanism 22, and a control part 23. The stage 21 holds a substrate S. An upper surface of the stage 21 is circular in the XY direction, the stage 21 can place one wafer-shaped (disc-shaped) substrate S so as a main surface of the substrate S to be in the horizontal direction (the XY direction). A center of the substrate S is disposed at a center C of the stage 21. The stage 21 is rotated about a vertical axis (dotted line) including the center C by the rotation mechanism 22. The stage 21 may rotate clockwise or counter-clockwise. As the stage 21 rotates, the substrate S held by the stage 21 rotates about the center C. A rotational motion and a rotation speed of the stage 21 driven by the rotation mechanism 22 is controlled by the control part 23. The rotation speed of the stage 21 controlled by the control part 23 may be, for example, 100 rpm or more and 500 rpm or less.

The solution supply part 10 is disposed above the stage 21. The solution supply part 10 includes a nozzle 11, a flow path 12, a valve 13, a filter 14, a solution supply device 15, and a drive mechanism 16. The solution supply part 10 supplies the freezing solution or the thawing solution onto the stage 21 (here, use the term solution when the freezing solution or thawing solution is not distinguished from each other). The flow path 12 is connected to the solution supply device 15 for supplying the solution. Here, the freezing solution and the thawing solution are, for example, deionized water (DIW). The solution supply device 15 supplies the solution to the flow path 12 while adjusting a flow rate and a temperature of the solution. Between the solution supply device 15 and the nozzle 11, the valve 13 and the filter 14 are arranged in this order. By opening the valve 13, the solution is supplied from the nozzle 11 through the filter 14 on the stage 21. The drive mechanism 16, for example, during the loading and unloading of the substrate S to the substrate processing apparatus 1, can move the solution supply part 10 from above the stage 21.

The nozzle 11 is disposed above the stage 21 extends in a diametrical direction (X direction, long side direction) including the center C of the stage 21. The nozzle 11, for example, one end of the long side direction is located outside the center of the stage 21, the other end of the long side direction is located outside the center of the stage 21 in a plan view. The nozzle 11 includes a solution reservoir 111 and a solution supply port 112. The solution supplied from the flow path 12 is temporarily stored in the solution reservoir 111. The solution stored in the solution reservoir 111 is discharged onto the substrate S from the solution supply port 112 facing a cleaning region (main surface) of the substrate S placed on the stage 21. Since the nozzle 11 has the solution reservoir 111, the flow rate of the solution supplied from the flow path 12 can be controlled, and a pressure applied to a connection part between the flow path 12 and the solution reservoir 111 can be dispersed. Since the nozzle 11 has the solution reservoir 111, the flow rate of the solution discharged from the solution supply port 112 can be controlled. In the present embodiment, the nozzle 11 has a rectangular shape, but the shape of the nozzle 11 is not particularly limited as long as a solution supply port 112, which will be described later, can be disposed. The shape of the solution reservoir 111 is also not particularly limited. It should be sufficient to store enough solution to be dispensed from the solution supply port 112.

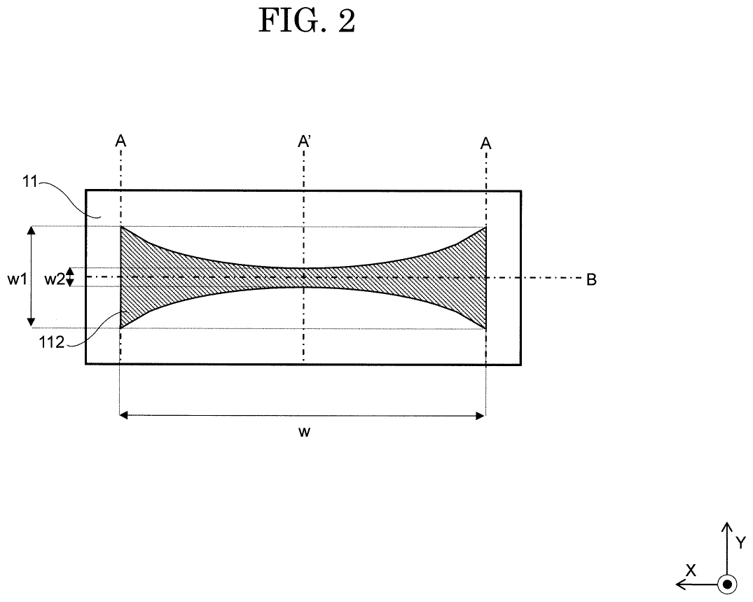

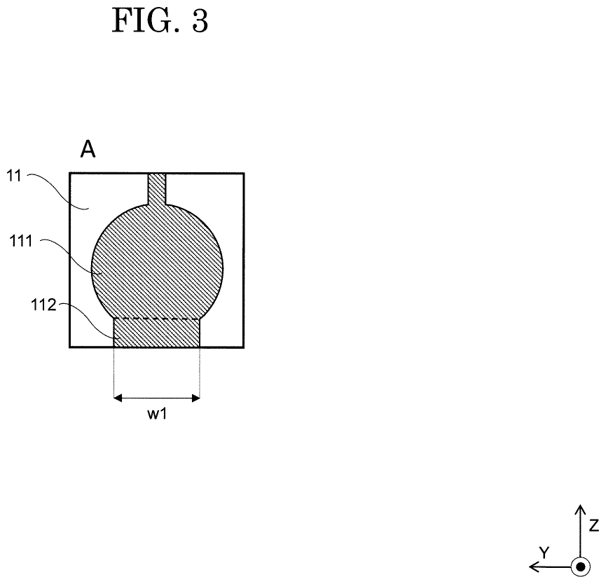

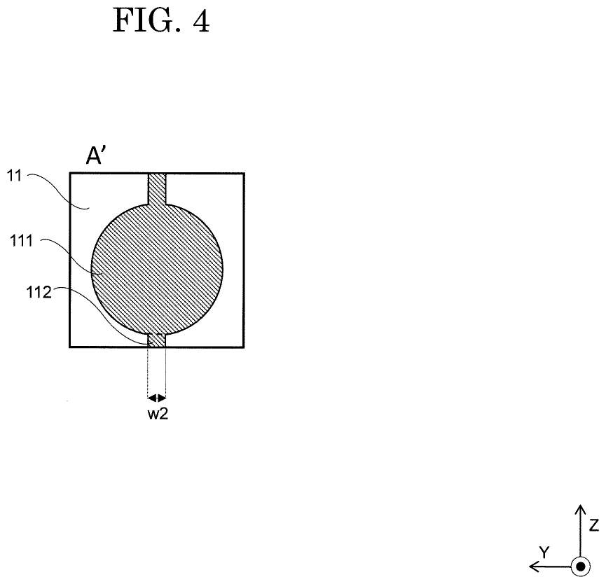

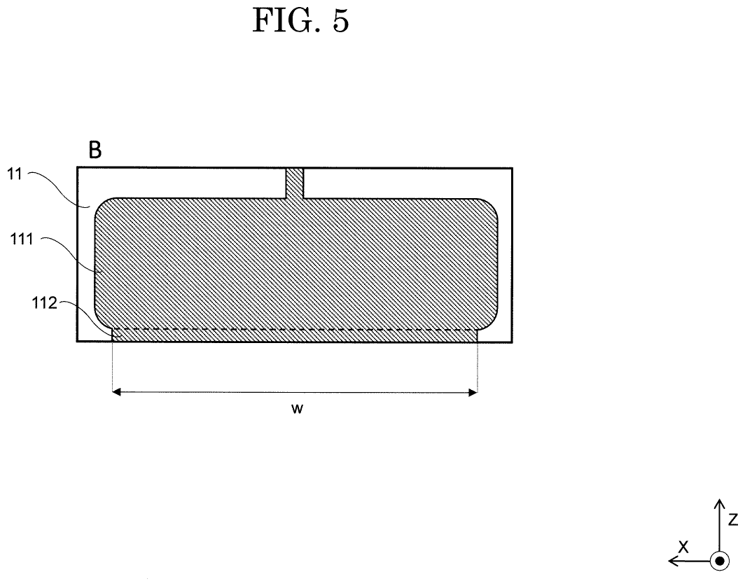

With reference to FIG. 1 to FIG. 5, a detailed description of the arrangement and shape of the solution supply port 112 of the nozzle 11 will be given. FIG. 2 is a bottom view schematically showing a structure of the nozzle according to an embodiment. FIG. 3 is a YZ sectional view of an end of long side (a position A in FIG. 2) of the nozzle 11. FIG. 4 is a YZ sectional view of a center of long side (a position A′ in FIG. 2) of the nozzle 11. FIG. 5 is an XZ sectional view of a center of short side (a position B in FIG. 2) of the nozzle 11.

The solution supply port 112 is disposed in a slit shape having substantially the same length as a diameter of the substrate S in the X direction in which the nozzle 11 extends. That is, a width w of the solution supply port 112 in a long side direction (the X direction) is substantially the same length as the diameter of the substrate S. The both ends of the long side (the position A in FIG. 2) of the solution supply port 112 is located on a both ends of the diameter of the substrate S (the outer periphery). That is, the both ends of the long side (the position A in FIG. 2) of the solution supply port 112 is located above substantially both ends of the diameter of the stage (the outer periphery). The center of the long side (the position A′ in FIG. 2) of the solution supply port 112 is located above the central part (the center C of the stage 21) of the substrate S. Since the width w of the solution supply port 112 in the long side direction (the X direction) has substantially the same length as the diameter of the substrate S, when the stage 21 rotates, the solution can be simultaneously supplied from the solution supply port 112 to substantially the entire surface of the substrate S. However, the width w of the solution supply port 112 in the long side direction (the X direction) may be substantially the same as a radius of the substrate S. In this case, the both ends of the long side of the solution supply port 112 is disposed so as to be positioned above both ends of the radius of the substrate S (the outer periphery and the central part).

A width w1 of the solution supply port 112 in a short side direction (Y direction) at the both ends of the long side (the position A in FIG. 2) is larger than a width w2 of the solution supply port 112 in a short side direction (the Y direction) at the center of the long side (the position A′ in FIG. 2). That is, the width w1 of the solution supply port 112 facing the outer periphery of the substrate S is larger than the width w2 of the solution supply port 112 facing the central part of the substrate S. The width w1 of the solution supply port 112 in the short side direction (the Y direction) at the both ends of the long side (the position A in FIG. 2) is preferably 1.4 times or more and 2 times or less of the width w2 of the solution supply port 112 in the short side direction (the Y direction) at a center of the long side (the position A′ in FIG. 2).

In the solution supply port 112 according to the present embodiment, the width w1 at the both ends of the long side (the position A in FIG. 2) and the width w2 at the center of the long side (the position A′ in FIG. 2) are different from each other, whereby the supply volume of the solution can be controlled. Since the width w1 of the solution supply port 112 at the both ends of the long side (the position A in FIG. 2) is larger than the width w2 of the solution supply port 112 at the center of the long side (the position A′ in FIG. 2), a supply volume of the solution discharged from the both ends of the long side (the position A in FIG. 2) of the solution supply port 112 is larger than the supply volume of the solution discharged from the center of the long side (the position A′ in FIG. 2) of the solution supply port 112. Therefore, the substrate processing apparatus 1 according to the present embodiment can supply a larger volume of the solution to the outer periphery of the substrate S than to the central part of the substrate S.

In this embodiment, the solution supply part 10 has shown a configuration in which the freezing solution or a thawing solution is supplied onto the stage 21. However, the present invention is not limited thereto, and the freezing solution may be supplied by another solution supply part. In this case, the shape of the nozzle of the other solution supply part that supplies the freezing solution is not particularly limited. It is sufficient that the freezing solution can be uniformly supplied onto the substrate S.

Above the stage 21, the cooling part 30 is disposed. The cooling part 30 supplies a cooled gas on the stage 21. The cooling part 30 may be, for example, a gas supply nozzle. The cooled gas cools the freezing solution supplied onto the substrate S to solidify, for example, to freeze. The gas is, for example, nitrogen gas, and a temperature of the gas is, for example, equal to or lower than the freezing point of a solution film. The cooling part 30 supplies the gas on the substrate S while adjusting the flow rate and the temperature. Instead of the cooling part 30, for example, a cooling gas may be supplied below the substrate S from a through hole provided in the stage 21. In that case, the cooling gas is supplied to the back surface of the substrate S.

### [Method of Substrate Processing]

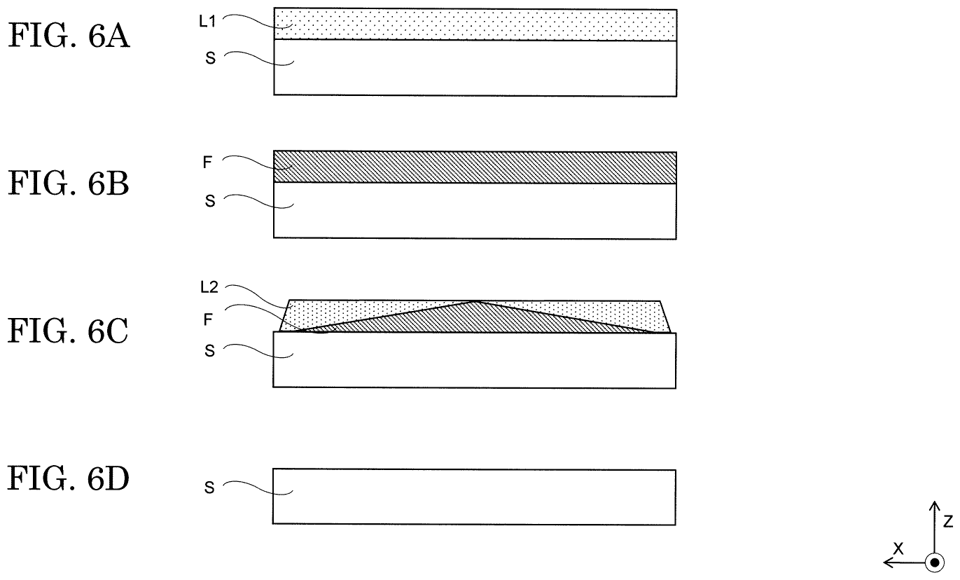

Hereinafter, a method of substrate processing using the substrate processing apparatus 1 according to the present embodiment will be described. The method of substrate processing according to the present embodiment is, for example, a method for performing the freezing cleaning process for removing particles and the like from the substrate surface by supplying the freezing solution to the surface of the semiconductor substrate, cooling the freezing solution to form the freezing film, and thawing the freezing film by supplying the thawing solution. The method of substrate processing of the embodiment can be performed, for example, as a part of a manufacturing process of a semiconductor device. FIG. 6A to FIG. 6D schematically shows the method of substrate processing according to the embodiment. In FIG. 6A to FIG. 6D, the configuration of the substrate processing apparatus 1 is omitted in order to explain the state above the substrate S.

As shown in FIG. 1, first, the substrate S is placed on the stage 21 so that the main surface of the substrate to be horizontal direction (the XY direction). The substrate S is, for example, a semiconductor substrate. The stage 21 holding the substrate S is rotated about a vertical axis including the center C by the rotation mechanism 22.

In order to supply the freezing solution, the valve 13 of the solution supply part 10 is opened to supply the freezing solution to the substrate S. The freezing solution is, for example, deionized water (DIW). The freezing solution is supplied onto the substrate S via the filter 14. A shape of the nozzle 11 and a shape of the solution supply port 112 for supplying the freezing solution are not particularly limited. As shown in FIG. 6A, the supplied freezing solution forms a uniform freezing solution film L1 on the surface of the substrate S.

Supplying the cooled gas from the cooling part 30. The gas is, for example, nitrogen gas, and the temperature of the gas is, for example, equal to or lower than the freezing point of the solution film. As shown in FIG. 6B, the cooled gas cools the freezing solution film to form a uniform freezing film F on the surface of the substrate S. In the freezing film F, incrustation such as particles adhering to the substrate surface is taken in.

In order to supply the thawing solution, the valve 13 of the solution supply part 10 is opened to supply the thawing solution to the substrate S. The thawing solution is, for example, deionized water (DIW). The thawing solution is supplied onto the substrate S from the nozzle 11 via the filter 14. In the present embodiment, since the width w1 of the solution supply port 112 at the both ends of the long side (the position A in FIG. 2) is larger than the width w2 of the solution supply port 112 at the center of the long side (the position A′ in FIG. 2), a gradient can be created in the supply volume of thawing solution discharged from the solution supply port 112. The supply volume of the thawing solution discharged from the both ends of the long side (the position A in FIG. 2) of the solution supply port 112 is larger than the supply volume of the thawing solution discharged from the center of the long side (the position A′ in FIG. 2) of the solution supply port 112. It is preferable that the supply volume of the thawing solution discharged from the both ends of the long side (the position A in FIG. 2) of the solution supply port 112 is 4 times or more and 5 times or less of the supply volume of the thawing solution discharged from the center of the long side (the position A′ in FIG. 2) of the solution supply port 112.

The supply volume of the thawing solution supplied to the outer periphery of the substrate S is larger than the supply volume of the thawing solution supplied to the central part of the substrate S. As a result, the freezing film F on the surface of the substrate S is thawed from the outer periphery part of the substrate S. As shown in FIG. 6C, the film thickness of the freezing film F remaining on the surface of the substrate S forms a smooth gradient that is thick in the central part of the substrate S, and is thin in the outer periphery of the substrate S. When the freezing film F on the substrate S is thawed from the outer periphery, the incrustation taken into the freezing film F of the outer periphery of the substrate S is discharged to the outside of the substrate S together with the thawing solution. On top of the freezing film F remaining on the surface of the substrate S, the supplied thawing solution forms a thawing solution film L2. In FIG. 6C, the film thickness of the thawing solution film L2 forms a gradient opposite to that of the freezing film F, and the film thickness of the thawing solution film L2 is thin at the center of the substrate S and thick at the outer periphery of the substrate S. However, the present invention is not limited thereto, and the thawing solution does not have to form the thawing solution film L2 on the freezing film F.

When the remaining freezing film F on the central part of the substrate S is thawed, the incrustation taken in the freezing film F on the central part of the substrate S is discharged to the outside of the substrate S together with the thawing solution. As shown in FIG. 6D, when all of the freezing film F are thawed, the incrustation that has been incorporated into the freezing film F is discharged out of the substrate S together with the thawing solution.

When the freezing film F on the surface of the substrate S is thawed from the central part of the substrate S, the freezing film F remaining on the outer periphery of the substrate S may hinder the movement of incrustation such as particles attached to the central part of the substrate S. In the method of substrate processing according to the present embodiment, by thawing the freezing film F on the surface of the substrate S from the outer periphery of the substrate S, it is possible to efficiently remove incrustation such as particles adhering to the central part of the substrate S, and it is possible to improve the freezing cleaning efficiency of the substrate S.

### Modified Example

A configuration of a substrate processing apparatus according to a present modified example is the same as the configuration of the substrate processing apparatus according to the first embodiment except for a shape of a solution supply port of the nozzle. The method of substrate processing according to the present modified example is the same as the substrate processing method according to the first embodiment. Descriptions that are the same as those of the first embodiment are omitted, and portions different from the configuration of the substrate processing apparatus according to the first embodiment will be described.

### [Substrate Processing Apparatus]

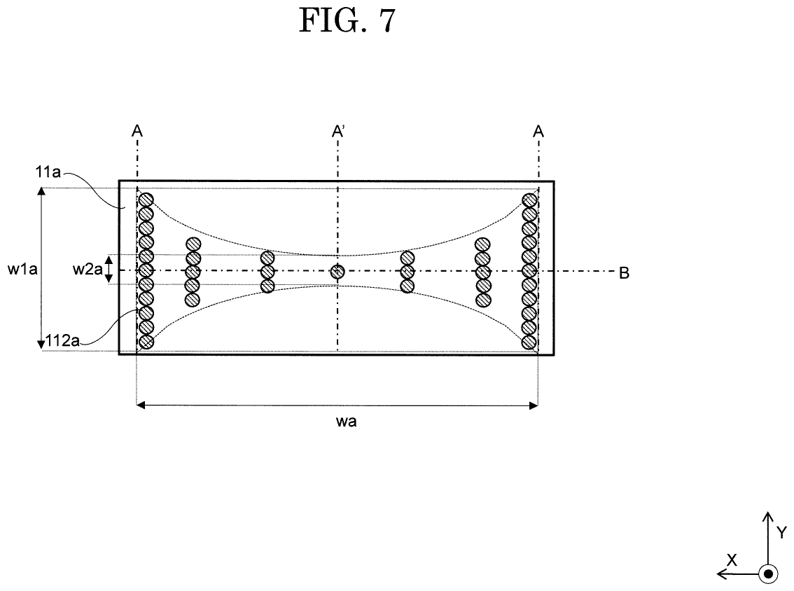

FIG. 7 is a bottom view schematically showing a structure of a nozzle according to a modified example. As shown in FIG. 7, a nozzle 11a includes a plurality of solution supply ports 112a. The plurality of solution supply ports 112a are connected to one solution reservoir.

The plurality of solution supply ports 112a are arranged in the same region as the region (dotted line) in which the solution supply ports 112 according to the first embodiment are arranged. That is, a width wa of the region where the plurality of solution supply ports 112a are arranged in the long side direction (the X direction) is substantially the same length as the diameter of the substrate S. A width w1a of the region where the plurality of solution supply ports 112a are arranged in the short side direction (the Y direction) at the both ends of the long side (a position A in FIG. 7) is larger than a width w2a of the region where the plurality of solution supply ports 112a are arranged in the short side direction (the Y direction) at the center of the long side (a position A′ in FIG. 7). The plurality of solution supply ports 112a are scattered about the above-mentioned region (dotted line).

In the present modified example, the plurality of solution supply ports 112a are circular in shape and have the same size. The number of the plurality of solution supply ports 112a is larger at the both ends of the long side (the position A in FIG. 7) than at the center of the long side (the position A′ in FIG. 7) of the region where the plurality of solution supply ports 112a are arranged. It is preferable that the number of the solution supply ports 112a at the both ends of the long side (the position A in FIG. 7) is 2 times or more and 3 times or less of the number of the solution supply ports 112a at the center of the long side (the position A′ in FIG. 7) of the region where the plurality of solution supply ports 112a are arranged. However, it is not limited to this. As described later, the size (area) of the plurality of solution supply ports 112a may be larger at the both ends of the long side (the position A in FIG. 7) than at the center of the long side (the position A′ in FIG. 7) of the region where the plurality of solution supply ports 112a are arranged. In this case, the number of the plurality of solution supply ports 112a may be the same at the center of the long side (the position A′ in FIG. 7) and at the both ends of the long side (the position A in FIG. 7) of the region where the plurality of solution supply ports 112a are arranged.

The solution supply port 112a according to the present embodiment can control the supply volume of the solution by differing the number of the plurality of solution supply ports 112a at the center of the long side (the position A′ in FIG. 7) and at the both ends of the long side (the position A in FIG. 7). Since the number of the solution supply ports 112a at the both ends of the long side (the position A in FIG. 7) is larger than the number of the solution supply ports 112a at the center of the long side (the position A′ in FIG. 7), the supply volume of the solution discharged from the both ends of the long side (the position A in FIG. 7) of the solution supply port 112a is larger than the supply volume of the solution discharged from the center of the long side (the position A′ in FIG. 7) of the solution supply port 112a. Therefore, the substrate processing apparatus according to the present modified example can supply more solution to the outer periphery of the substrate S than to the central part of the substrate S.

### Second Embodiment

### [Substrate Processing Apparatus]

A configuration of a substrate processing apparatus according to the present embodiment is the same as the configuration of the substrate processing apparatus according to the first embodiment except for a configuration of the nozzle. The method of substrate processing according to the present embodiment is the same as the method of substrate processing according to the first embodiment except for a temperature of a thawing solution. Descriptions that are the same as those of the first embodiment are omitted, and portions different from the configuration of the substrate processing apparatus according to the first embodiment will be described.

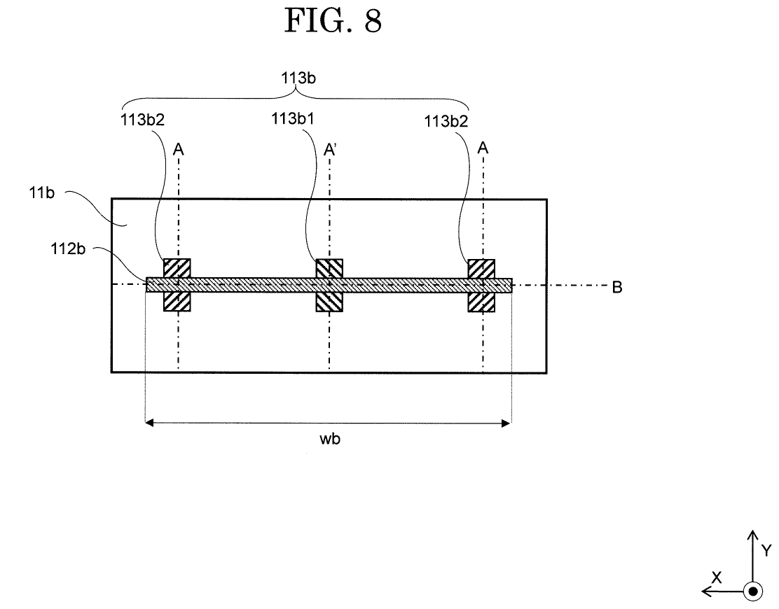

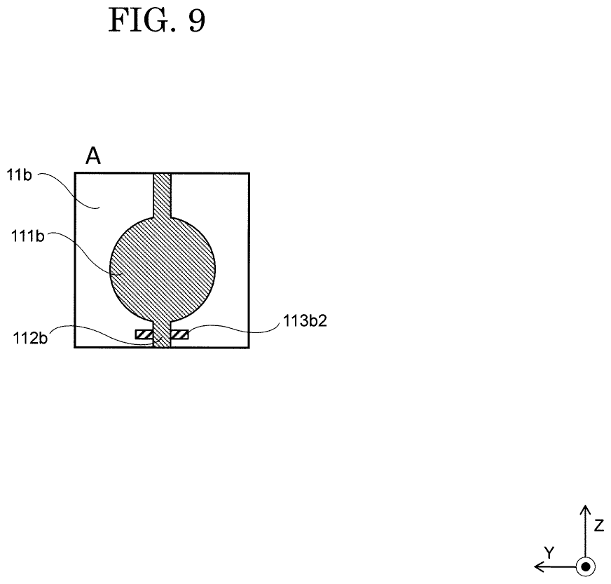

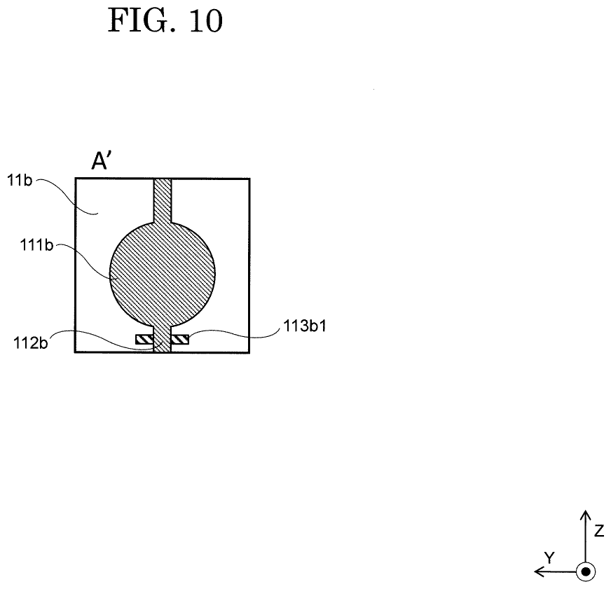

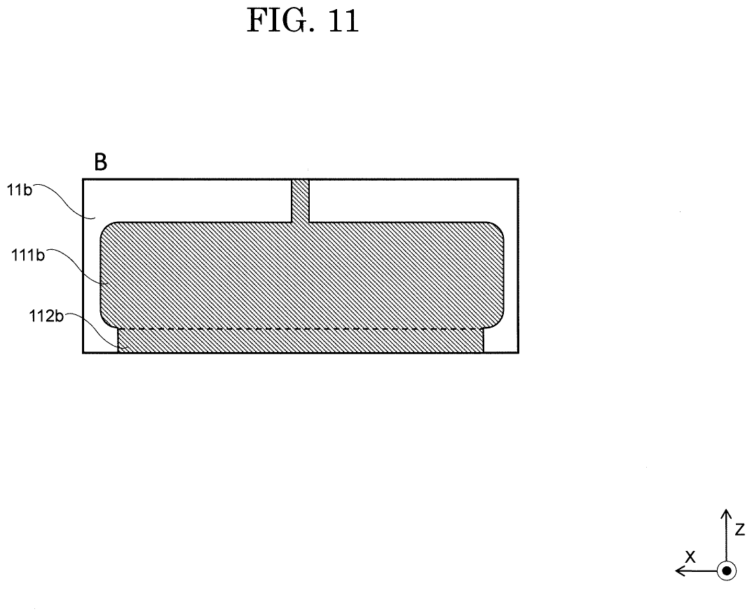

A configuration of a nozzle 11b will be described in detail with reference to FIG. 1 and FIG. 8 to FIG. 11. FIG. 8 is a bottom view schematically showing a structure of the nozzle according to an embodiment. FIG. 9 is a YZ sectional view of an end of long side (the position A in FIG. 8) of the nozzle 11b. FIG. 10 is a YZ sectional view of the center of the long side (the position A′ in FIG. 8) of the nozzle 11b. FIG. 11 is an XZ sectional view of the center of the short side (the position B in FIG. 8) of the nozzle 11b. In the present embodiment, the nozzle 11b includes a solution reservoir 111b, a solution supply port 112b, and a temperature control mechanism 113b.

The solution supply port 112b is disposed in a slit shape having substantially the same length as the diameter of the substrate S in the X direction in which the nozzle 11b extends. That is, a width wb of the solution supply port 112b in the long side direction (the X direction) is substantially the same length as the diameter of the substrate S. A width of the solution supply port 112b in the short side direction (the Y direction) is substantially the same over the long side direction (the X direction). However, the width of the solution supply port 112b in the short side direction (the Y direction) may be different between the end of the long side and the center of the long side as in the first embodiment.

The nozzle 11b includes the temperature control mechanism 113b adjacent to the solution supply port 112b. The temperature of the solution discharged from the solution supply port 112b onto the substrate S is controlled by the temperature control mechanism 113b. The temperature control mechanism 113b may include either one of a cooler 113b1 or a heater 113b2, and may include both the cooler 113b1 and the heater 113b2. The heater 113b2 is disposed, for example, at the ends of the long side (the position A in FIG. 8) of the solution supply port 112b. The cooler 113b1 is disposed, for example, at the center of the long side (the position A′ in FIG. 8) of the solution supply port 112b. In FIG. 8, the temperature control mechanism 113b is adjacent to the outside of the solution supply port 112b, but may be disposed inside the solution supply port 112b. The temperature control mechanism 113b only needs to be able to partly control the temperature of the solution discharged from the solution supply port 112b onto the substrate S. The temperature control mechanism 113b may further include a temperature sensor. The sensor may be disposed inside the solution supply port 112b.

The temperature control mechanism 113b according to the present embodiment can control the temperature of the solution discharged from the both ends of the long side (the position A in FIG. 8) of the solution supply port 112b and the temperature of the solution discharged from the center of the long side (the position A′ in FIG. 8) of the solution supply port 112b. By placing the heater 113b2 on the both ends of the long side (the position A in FIG. 8) of the solution supply port 112b, and placing the cooler 113b1 on the center of the long side (the position A′ in FIG. 8) of the solution supply port 112b, the temperature of the solution discharged from the both ends of the long side (the position A in FIG. 8) of the solution supply port 112b is higher than the temperature of the solution discharged from the center of the long side (the position A′ in FIG. 8) of the solution supply port 112b. Therefore, the substrate processing apparatus according to the present embodiment can supply a solution with a higher temperature to the outer periphery of the substrate S than to the central part of the substrate S.

### [Method of Substrate Processing]

Since a method of substrate processing according to the present embodiment is the same as the method of substrate processing according to the first embodiment except for the temperature of the thawing solution, only a portion different from the first embodiment in a supply of the thawing solution will be described here.

In the present embodiment, the heater at the both ends of the long side (the position A in FIG. 8) of the solution supply port 112b and the cooler at the center of the long side (the position A′ in FIG. 8) are arranged, so that the temperature of the thawing solution discharged from the solution supply port 112b can be graded. The temperature of the thawing solution discharged from the both ends of the long side (the position A in FIG. 8) of the solution supply port 112b is higher than the temperature of the thawing solution discharged from the center of the long side (the position A′ in FIG. 8) of the solution supply port 112b. The temperature of the thawing solution discharged from the both ends of the long side (the position A in FIG. 8) of the solution supply port 112b may be, for example, about 20° C. or more and 25° C. or less. The temperature of the thawing solution discharged from the center of the long side (the position A′ in FIG. 8) of the solution supply port 112b may be, for example, about 3° C. or more and 5° C. or less. It is preferable that the difference between the temperature of the thawing solution discharged from the both ends of the long side (the position A in FIG. 8) of the solution supply port 112b and the temperature of the thawing solution discharged from the center of the long side (the position A′ in FIG. 8) of the solution supply port 112b is about 15° C. or more and 20° C. or less.

The temperature control mechanism 113b in the present embodiment shows a configuration including both the cooler 113b1 and the heater 113b2. However, the present invention is not limited to this, and only one of the cooler 113b1 and the heater 113b2 may be used depending on the temperature of the thawing solution supplied from the flow path 12. When the temperature of the supplied thawing solution is, for example, about 10° C., a gradient may be formed in the temperature of the thawing solution discharged from the solution supply port 112b by heating the thawing solution with the heaters 113b2 at the both ends of the long side (the position A in FIG. 8) of the solution supply port 112b. When the temperature of the supplied thawing solution is, for example, about 25° C., a gradient may be formed in the temperature of the thawing solution discharged from the solution supply port 112b by cooling the thawing solution with the cooler 113b1 at the center of the long side (the position A′ in FIG. 8) of the solution supply port 112b.

The temperature of the thawing solution supplied to the outer periphery of the substrate S is higher than the temperature of the thawing solution supplied to the central part of the substrate S. As a result, the freezing film F on the surface of the substrate S is thawed from the outer periphery of the substrate S. As shown in FIG. 6C, the film thickness of the freezing film F remaining on the surface of the substrate S forms a smooth gradient that is thick in the central part of the substrate S, and is thin in the outer periphery of the substrate S. When the freezing film F on the substrate S is thawed from the outer periphery, the incrustation taken into the freezing film F of the outer periphery of the substrate S is discharged to the outside of the substrate S together with the thawing solution. When the remaining freezing film F on the central part of the substrate S is thawed, the incrustation taken in the freezing film F on the central part of the substrate S is discharged to the outside of the substrate S together with the thawing solution. In the method of substrate processing according to the present embodiment, by thawing the freezing film F on the surface of the substrate S from the outer periphery of the substrate S, it is possible to efficiently remove incrustation such as particles adhering to the central part of the substrate S, and it is possible to improve the freezing cleaning efficiency of the substrate S.

### Third Embodiment

### [Substrate Processing Apparatus]

A configuration of a substrate processing apparatus according to the present embodiment is the same as that of the substrate processing apparatus according to the first embodiment except that a plurality of flow paths is provided. The method of substrate processing according to the present embodiment is the same as the method of substrate processing according to the first embodiment except for a temperature of a thawing solution. Descriptions that are the same as those of the first embodiment are omitted, and portions different from the configuration of the substrate processing apparatus according to the first embodiment will be described.

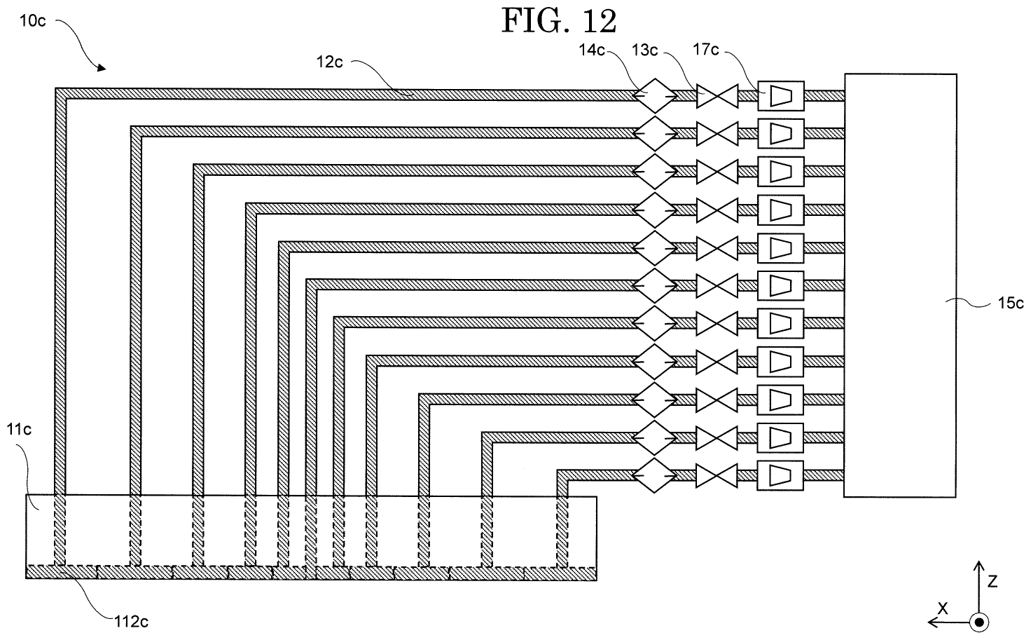

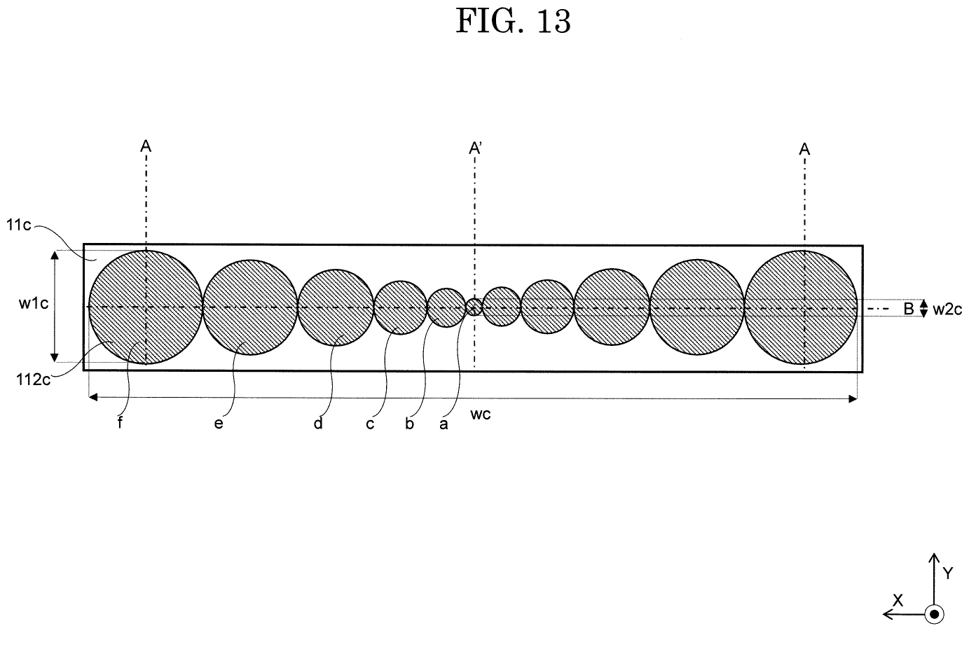

The configuration of the solution supply part will be described in detail with reference to FIG. 12 and FIG. 13. FIG. 12 is a diagram schematically showing the overall configuration of the solution supply part according to an embodiment. FIG. 13 is a bottom view schematically showing a structure of the nozzle according to an embodiment.

A solution supply part 10c includes a nozzle 11c, a flow path 12c, a valve 13c, a filter 14c, a solution supply device 15c, and a mass flow controller 17c. In the present embodiment, the solution supply part 10c includes a plurality of flow paths 12c. Each of the flow paths 12c is connected to the solution supply device 15c for supplying a solution. The solution supply device 15c supplies the solution of different timing, supply volume, and temperature to the respective flow paths 12c. Between the solution supply device 15c and the nozzle 11c of the respective flow path 12c, the mass flow controller 17c and the valve 13c and the filter 14c are arranged in this order. The mass flow controller 17c controls the flow rate by changing the flow path resistance. By opening the valve 13c, solution is supplied from the nozzle 11c through the filter 14c on the stage 21. Although omitted a drive mechanism in FIG. 12, the solution supply part 10c may be provided with the drive mechanism in the same manner as in the first embodiment.

The nozzle 11c includes a plurality of solution supply ports 112c. The corresponding flow paths 12c are connected to the respective solution supply ports 112c in a one-to-one manner. Although a solution reservoir is omitted in FIG. 12, the solution reservoir may be provided between each of the flow paths 12c and the solution supply port 112c in the same manner as in the first embodiment.

The plurality of solution supply ports 112c are disposed in the same region as the region where the solution supply port 112 according to the first embodiment is disposed. That is, a width wc of the region where the plurality of solution supply ports 112c are arranged in the long side direction (the X direction) is substantially the same length as the diameter of the substrate S. The plurality of solution supply ports 112c are scattered about the above-mentioned region.

In this embodiment, each of the plurality of solution supply ports 112c has a different size. The size of the solution supply port 112c disposed at both ends of the long side (a position A in FIG. 13) is larger than the size of the solution supply port 112c disposed at the center of the long side (a position A′ in FIG. 13) of the region where the plurality of solution supply ports 112c are disposed. The size of the solution supply port 112c disposed at the both ends of the long side (the position A in FIG. 13) is preferably 2 times or more and 4 times or less of the size of the solution supply port 112c disposed at the center of the long side (the position A′ in FIG. 13) of the region where the plurality of solution supply ports 112c are disposed, and more preferably 2 times or more and 3 times or less. Here, the size of the solution supply port 112c indicates the area of the solution supply port 112c.

A diameter w1c of the solution supply port 112c disposed at the both ends of the long side (the position A in FIG. 13) is larger than a diameter w2c of the solution supply port 112c disposed at the center of the long side (the position A′ in FIG. 13) of the region where the plurality of solution supply ports 112c are disposed. The diameter w1c of the solution supply port 112c disposed at the both ends of the long side (the position A in FIG. 13) is preferably 1.41 times or more and 2 times or less, more preferably 1.41 times or more and 1.73 times or less, of the diameter w2c of the solution supply port 112c disposed at the center of the long side (the position A′ in FIG. 13) of the region where the plurality of solution supply ports 112c are disposed. Here, the diameter of the solution supply port 112c indicates the width of the solution supply port 112c in the short side direction (the Y direction).

The shape of the plurality of solution supply ports 112c is circular, but is not particularly limited. FIG. 13 shows examples of different sizes of the plurality of solution supply ports 112c, but not limited to the size of the plurality of solution supply ports 112c, the size of the plurality of solution supply ports 112c should be large enough to allow stable dispensing of the flow rate of solution as described below.

The solution supply device 15c includes a flow rate control mechanism, a timing control mechanism, and a temperature control mechanism for supplying a solution of different supply volumes, timings, and temperatures to the respective flow paths 12c.

The flow rate of the solution discharged from the solution supply port 112c onto the substrate S is controlled by the flow rate control mechanism of the solution supply device 15c. The flow rate control mechanism can control the flow rate of the solution discharged from the solution supply port 112c disposed at the both ends of the long side (the position A in FIG. 13), and the flow rate of the solution discharged from the solution supply port 112c disposed at the center of the long side (the position A′ in FIG. 13) of the region where the plurality of solution supply ports 112c are disposed. The flow rate of the solution supplied to the solution supply port 112c disposed at the both ends of the long side (the position A in FIG. 13) is larger than the flow rate of the solution supplied to the solution supply port 112c disposed at the center of the long side (the position A′ in FIG. 13) of the region where the plurality of solution supply ports 112c are disposed. It is preferable that the flow rate of the solution discharged from the solution supply port 112c disposed at the both ends of the long side (the position A in FIG. 13) is 15 times or more of the flow rate of the solution discharged from the solution supply port 112c disposed at the center of the long side (the position A′ in FIG. 13) of the region where the plurality of solution supply ports 112c are disposed. Therefore, the substrate processing apparatus according to the present embodiment can supply larger solution volume to the outer periphery of the substrate S than to the central part of the substrate S.

The timing of the solution discharged from the solution supply port 112c onto the substrate S is controlled by the timing control mechanism of the solution supply device 15c. The timing control mechanism can control the timing of the solution discharged from the solution supply port 112c disposed at the both ends of the long side (the position A in FIG. 13), and the timing of the solution discharged from the solution supply port 112c disposed at the center of the long side (the position A′ in FIG. 13) of the region where the plurality of solution supply ports 112c are disposed. The timing of the solution supplied to the solution supply port 112c disposed at the both ends of the long side (the position A in FIG. 13) is earlier than the timing of the solution supplied to the solution supply port 112c disposed at the center of the long side (the position A′ in FIG. 13) of the region where the plurality of solution supply ports 112c are disposed. Therefore, the substrate processing apparatus according to the present embodiment can supply the solution to the outer periphery of the substrate S earlier than the central part of the substrate S. When a supply time of the solution discharged from the solution supply port 112c disposed at the both ends of the long side (the position A in FIG. 13) of the region where the plurality of solution supply ports 112c are disposed is 5 sec, it is preferable that the supply time of the solution discharged from the solution supply port 112c disposed at the center of the long side (the position A′ in FIG. 13) is 1.2 sec or more and 1.6 sec or less. It is preferable to delay the timing of the solution discharged from the solution supply port 112c disposed at the center of the long side (the position A′ in FIG. 13) by the difference between the supply time of the solution discharged from the solution supply port 112c disposed at the center of the long side (the position A′ in FIG. 13) and the supply time of the solution discharged from the solution supply port 112c disposed at the both ends of the long side (the position A in FIG. 13). Therefore, it is preferable that the timing of the solution discharged from the solution supply port 112c disposed at the center of the long side (the position A′ in FIG. 13) is delayed by 3.4 sec or more and 3.8 sec or less.

The temperature of the solution discharged from the solution supply port 112c onto the substrate S is controlled by the temperature control mechanism of the solution supply device 15c. The temperature control mechanism can control the temperature of the solution discharged from the solution supply port 112c disposed at the both ends of the long side (the position A in FIG. 13), and the temperature of the solution discharged from the solution supply port 112c disposed at the center of the long side (the position A′ in FIG. 13) of the region where the plurality of solution supply ports 112c are disposed. The temperature of the solution supplied to the solution supply port 112c disposed at the both ends of the long side (the position A in FIG. 13) is higher than the temperature of the solution supplied to the solution supply port 112c disposed at the center of the long side (the position A′ in FIG. 13) of the region where the plurality of solution supply ports 112c are disposed. It is preferable that the temperature of the solution supplied to the solution supply port 112c disposed at the center of the long side (the position A′ in FIG. 13) of the region where the plurality of solution supply ports 112c are disposed is about 3° C. or more and 5° C. or less. It is preferable that the temperature of the solution supplied to the solution supply port 112c disposed at the both ends of the long side (the position A in FIG. 13) of the region where the plurality of solution supply ports 112c are disposed is about 20° C. or more and 25° C. or less. It is preferable that the difference between the temperature of the solution supplied to the solution supply port 112c disposed at the center of the long side (the position A′ in FIG. 13) and the temperature of the solution supplied to the solution supply port 112c disposed at the both ends of the long side (the position A in FIG. 13) of the region where the plurality of solution supply ports 112c are disposed is about 15° C. or more and 20° C. or less. Therefore, the substrate processing apparatus according to the present embodiment can supply a solution having a temperature higher to the outer periphery of the substrate S than to the central part of the substrate S.

### [Substrate Processing Method]

Since a method of substrate processing according to the present embodiment is the same as the method of substrate processing according to the first embodiment except for the flow rate, the timing, and the temperature of the thawing solution, only a portion different from the first embodiment in the supply of the thawing solution will be described here.

In the present embodiment, the flow rate of the thawing solution discharged from the solution supply port 112c can be graded by the flow rate control mechanism of the solution supply device 15c. The flow rate of the thawing solution discharged from the solution supply port 112c disposed at the both ends of the long side (the position A in FIG. 13) is larger than the flow rate of the thawing solution discharged from the solution supply port 112c disposed at the center of the long side (the position A′ in FIG. 13) of the region where the plurality of solution supply ports 112c are disposed.

In the present embodiment, the timing of the thawing solution discharged from the solution supply port 112c can be different by the timing control mechanism of the solution supply device 15c. The timing of the thawing solution discharged from the solution supply port 112c disposed at the both ends of the long side (the position A in FIG. 13) is earlier than the timing of the thawing solution discharged from the solution supply port 112c disposed at the center of the long side (the position A′ in FIG. 13) of the region where the plurality of solution supply ports 112c are disposed.

In the present embodiment, the temperature of the thawing solution discharged from the solution supply port 112c can be graded by the temperature control mechanism of the solution supply device 15c. The temperature of the thawing solution discharged from the solution supply port 112c disposed at the both ends of the long side (the position A in FIG. 13) is higher than the temperature of the thawing solution discharged from the solution supply port 112c disposed at the center of the long side (the position A′ in FIG. 13) of the region where the plurality of solution supply ports 112c are disposed.

The flow rate of the thawing solution supplied to the outer periphery of the substrate S is larger than the flow rate of the thawing solution supplied to the central part of the substrate S. The timing of the thawing solution supplied to the outer periphery of the substrate S is earlier than the timing of the thawing solution supplied to the center of the substrate S. The temperature of the thawing solution supplied to the outer peripheral part of the substrate S is higher than the temperature of the thawing solution supplied to the central part of the substrate S. As a result, the freezing film F on the surface of the substrate S is thawed from the outer periphery of the substrate S. As shown in FIG. 6C, the film thickness of the freezing film F remaining on the surface of the substrate S forms a smooth gradient that is thick in the central part of the substrate S, and is thin in the outer periphery of the substrate S. When the freezing film F on the substrate S is thawed from the outer periphery, the incrustation taken into the freezing film F of the outer periphery of the substrate S is discharged to the outside of the substrate S together with the thawing solution. When the remaining freezing film F on the central part of the substrate S is thawed, the incrustation taken in the freezing film F in the central part of the substrate S is discharged to the outside of the substrate S together with the thawing solution. In the method of substrate processing according to the present embodiment, by thawing the freezing film F on the surface of the substrate S from the outer periphery of the substrate S, it is possible to efficiently remove incrustation such as particles adhering to the central part of the substrate S, and it is possible to improve the freezing cleaning efficiency of the substrate S.

### EXAMPLES

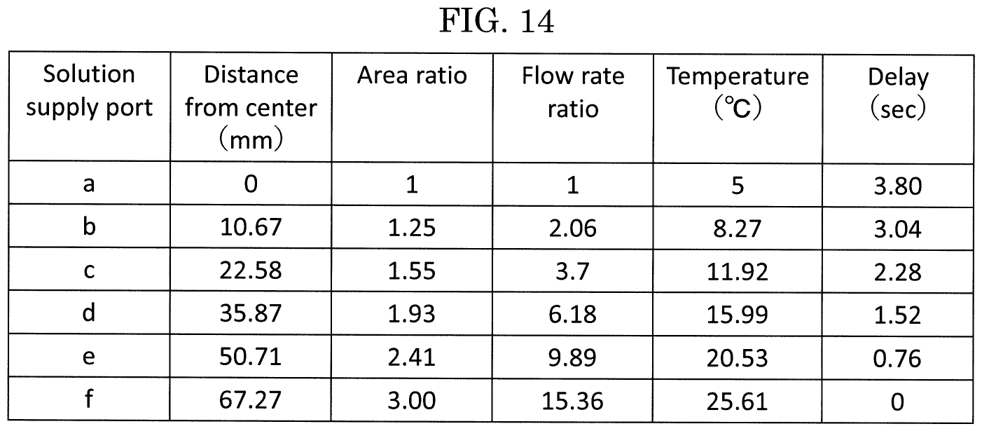

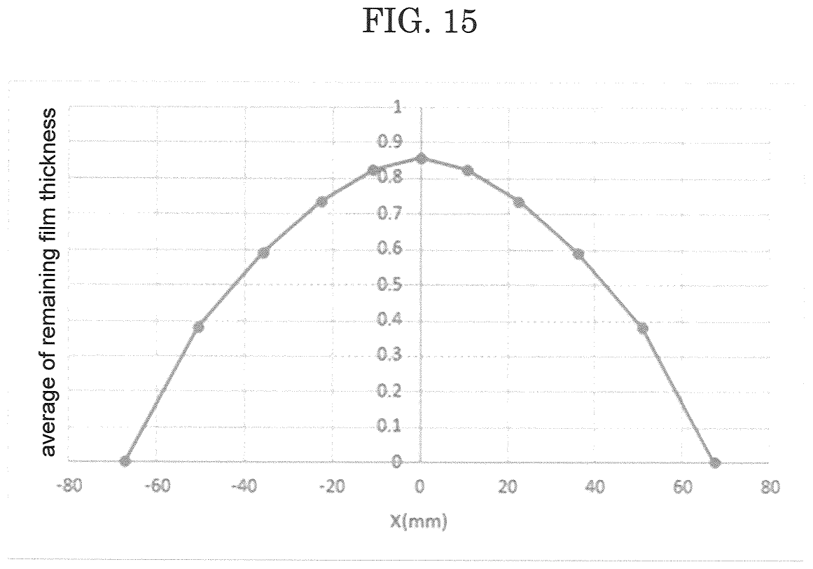

An example of a method of substrate processing using the substrate processing apparatus according to the third embodiment will be described with reference to FIG. 14 and FIG. 15. FIG. 14 shows conditions of the method of substrate processing according to an example. FIG. 15 is a diagram showing the method of substrate processing according to an example.

FIG. 14 shows a distance from the center of the long side (the position A′ in FIG. 13) of each of the solution supply ports 112c (a to f) shown in FIG. 13, an area ratio of each of the solution supply ports 112c, a flow rate ratio of the thawing solution supplied from each of the solution supply ports 112c, a temperature (° C.) of the thawing solution, and a delay (sec) of the timing of supplying the thawing solution. FIG. 15 shows an average of remaining film thickness of the freezing film F (corresponding to FIG. 6C) when the thawing solution is supplied under the conditions at the rotation speed of the stage 21 of 300 rpm and the processing time of 5 sec. As shown in FIG. 15, it is understood that the freezing film F on the surface of the substrate S is thawed from the outer periphery of the substrate S, and the film thickness of the freezing film F remaining on the surface of the substrate S forms a smooth gradient that is thick at the central part of the substrate S, and is thin in the outer periphery of the substrate S.

While several embodiments have been described above, these embodiments have been presented by way of example only and are not intended to limit the scope of the invention. The novel apparatus and methods described herein may be implemented in various other forms. In addition, various omissions, substitutions, and changes may be made to the forms of the apparatus and method described herein without departing from the spirit of the invention. The appended claims and their equivalents are intended to cover such forms and modifications as fall within the scope and spirit of the invention.

1-16. (canceled)

17. A substrate processing apparatus comprising:
a substrate holding part having a stage holding a substrate;
a freezing solution supply part supplying a freezing solution to the substrate;
a cooling part cooling the freezing solution to form a freezing film; and
a thawing solution supply part comprising:
a drive mechanism;
a solution supply device;
a flow path connected to the solution supply device; and
a nozzle connected to the flow path, the nozzle arranged above the stage in a first direction including a central part of the stage in a plan view,
wherein
a first end and a second end opposite to the first end of the nozzle in the first direction are both located on an outer periphery part outside of the central part, the nozzle has a plurality of solution supply ports including a plurality of first solution supply ports and a plurality of second solution supply ports, the plurality of first solution supply ports scattered in a radial direction of the substrate and facing the substrate, the plurality of second solution supply ports aligned in a direction perpendicular to the radial direction with respect to the plurality of first solution supply ports, and a number of the plurality of second solution supply ports at the outer periphery is larger than a number of the plurality of second solution supply ports at the central part.

18. The substrate processing apparatus according to claim 17, wherein the thawing solution supply part simultaneously supplies a different volume of thawing solution between the central part and the outer periphery part of the substrate to thaw the freezing film from the outer periphery part to the central part of the substrate.

19. The substrate processing apparatus according to claim 17, wherein a supply volume of the thawing solution on the outer periphery is larger than a supply volume of the thawing solution on the central part.

20. The substrate processing apparatus according to claim 17, wherein the thawing solution supply part has a flow control mechanism connected to each of the plurality of solution supply ports.

21. The substrate processing apparatus according to claim 17, wherein the thawing solution supply part has a timing control mechanism connected to each of the plurality of solution supply ports.

22. The substrate processing apparatus according to claim 17, wherein the thawing solution supply part has a temperature control mechanism controlling the temperature of the thawing solution supplied to the substrate.

23. The substrate processing apparatus according to claim 22, wherein the temperature control mechanism is arranged adjacent to each of the plurality of solution supply ports.

24. The substrate processing apparatus according to claim 22, wherein the temperature control mechanism has a cooler or a heater.

25. The substrate processing apparatus according to claim 17, wherein the thawing solution supply part has a temperature control mechanism connected to each of the plurality of solution supply ports.

26. The substrate processing apparatus according to claim 17, wherein a length of the nozzle is longer than a radius of the substrate.

27. The substrate processing apparatus according to claim 26, wherein a length of a region in which the plurality of first solution supply ports is arranged is the same as the radius of the substrate.

28. The substrate processing apparatus according to claim 17, wherein a length of the nozzle is longer than a diameter of the substrate.

29. The substrate processing apparatus according to claim 28, wherein a length of a region in which the plurality of first solution supply ports is arranged is the same as the diameter of the substrate.

30. The substrate processing apparatus according to claim 28, wherein a number of the plurality of first solution supply ports is five or more, and the number of the plurality of second solution supply ports is one or more at the center part and increases by one or more toward the outer periphery.

31. The substrate processing apparatus according to claim 17, wherein the nozzle has a solution reservoir between the flow path and the plurality of solution supply ports.

32. The substrate processing apparatus according to claim 17, wherein each of the plurality of solution supply ports are circular.

33. The substrate processing apparatus according to claim 17, wherein each of the plurality of solution supply ports are the same size.

34. The substrate processing apparatus according to claim 17, wherein the number of the plurality of solution supply ports at the outer periphery is 2 times or more and 3 times or less of the number of the plurality of solution supply ports at the central part.
